(19) United States
(12) Patent Application Publication
(10) Pub. No.: US 2008/0135096 A1
(43) Pub. Date: Jun. 12, 2008

(54) Optical concentrators having one or more line foci and related methods

(76) Inventor: Richard L. Johnson, Suffolk, VA (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 11/904,635

(22) Filed: Sep. 27, 2007

Related U.S. Application Data
(60) Provisional application No. 60/848,722, filed on Sep. 30, 2006.
(60) Provisional application No. 60/848,721, filed on Sep. 30, 2006.

(51) Int. Cl. H01L 31/04

(52) U.S. Cl. 136/259; 250/203.4

(57) ABSTRACT

In accordance with the present invention optical concentrators with one or more, preferably two, line foci are disclosed. Such optical concentrators preferably comprise primary and optional secondary optics that function as optical concentrators. Preferred exemplary optical concentrators in accordance with the present invention include one or more line foci in that rays incident and parallel to the optical axis of such optical concentrators are concentrated onto one or more distinct linear regions of focused light.

### CROSS-REFERENCE TO RELATED APPLICATION

The present application claims priority to U.S. Provisional Application No. 60/848,722 filed Sep. 30, 2006 and U.S. Provisional Application No. 60/848,721 filed Sep. 30, 2006, the entire contents of which are both incorporated herein by reference.

### TECHNICAL FIELD

The present invention is directed to optical concentrators, optical concentrator systems, and related methods such as those for solar applications that receive incident light and concentrate the light onto a target, such as a photovoltaic target or a target to be heated. In particular, the present invention is directed to optical concentrators having one or more line foci and related systems and methods.

### BACKGROUND

U.S. Pat. No. 4,169,738 discloses conventional linear optical concentrators that include non-coplanar receivers. FIG. 1 of the present application schematically represents the '738 design and similar designs as including two receivers, 81 and 82, arranged back to back at the base of a trough 80 and parallel to the optical axis. This effectively provides a two-sided receiver. As a direct consequence, unfortunately, the focus of the trough 80 must be such that the trough 80 profile has a large height/width ratio for designs that provide large concentration ratios (i.e. a large ratio between the width of the trough aperture and the height of the receivers, 81 and 82).

Large height/width ratios are not as problematic if such optical concentrators are deployed as part of a fixed array on a panel that articulates as a whole. However, as shown in FIG. 2 of the present application, such conventional designs are unsuitable for use as individually articulated modules. In particular troughs, 83 and 85 freely rotate equally about pivots, 84 and 87, respectively, until the top side of trough 83 impinges on the sidewall of trough 83 indicated by collision zone 86. The rotation angle at which this occurs is a function of the height/width ratio of the troughs and the separation distance between them. In order to space the troughs so as to eliminate the collision requires a separation between the troughs dₛ that is on the order of the trough width dₐ. This separation results in low overall area efficiency for the concentrator system that is not suitable for applications with limited area.

The location of the two receivers, 81 and 82, at the base of the trough 80 limits self-refrigeration. Whereas the location does provide a direct thermal path to the back of the trough 80 where additional convective fins may be employed, the thermal load on the receiver planes is conducted toward the trough base through a relatively narrow interface. Such narrow interfaces generally have a higher thermal resistance. This increases the change in temperature between the receivers and the self-refrigerating device(s) tending to result in a higher operating temperature of the receivers and decreasing the efficiency of the receivers.

U.S. Pat. No. 4,269,168 relates to concentrating modules that focus light in two dimensions and which are generally referred to as point concentrators. The '168 design discloses methods of concentrating solar radiation onto stationary receivers while allowing the concentrating elements (i.e., cover, reflectors, etc.) to articulate about a common axis. FIG. 3 of the present application reproduces FIG. 3 of the '168 patent and shows the use of plural receivers 96 within a concentrator module 92, the use of multiple surfaces 98, and the use of a transparent cover material 94 to encapsulate the reflectors. The modules described in the '168 patent are designed primarily as a heat transfer system and not a photovoltaic system. Self-refrigeration is thus not a concern.

Furthermore, because of the use of a fresnel cover over the entire aperture, the modules in the '168 patent provide minimal field of view with respect to diffuse sky radiation (off-axis radiation, for example). This makes them unsuitable for use as part of a self-powering mechanism. Such self-powering mechanisms may use a portion of the energy converted by the receivers, including captured diffuse sky radiation, to power control articulation mechanisms. This enables the concentrator system to track primary radiation sources, such as the sun, without relying on an external source of power. Self-power is useful in many instances, including initiating tracking activities when a receiver is not aimed at a light source such as the sun, for example. The limited field of view with respect to background radiation, which in the case of the sun is diffuse sky radiation, results in a concentrator that can produce power only when pointed at the sun. Such a concentrator cannot provide power to control and/or articulation mechanisms when the concentrator is oriented away from the sun. Such circumstances typically arise at sunrise when the concentrator is oriented westward after sunset the previous day. Similar circumstances may arise due to temporary shadowing caused by cloud cover or other obstructions.

Certain kinds of devices, such as those with individually articulating concentrators, utilize a low overall height for the optical component, so that the concentrators can articulate past each other freely. These devices are described in U.S. patent application Ser. No. 11/454,441, filed on Jun. 15, 2006 and entitled “Planar Concentrating Photovoltaic Panel With Individually Articulating Concentrator Elements” and U.S. patent application Ser. No. 11/654,256, filed on Jan. 17, 2007, and entitled “Concentrated Solar Panel and Related Systems and Methods,” which are commonly-owned by the assignee of record of the present application and which are incorporated by reference herein in their entirety.

### SUMMARY

The present invention provides optical concentrators having an axis of concentration and one or more line foci substantially parallel to such concentrating axis, preferably plural line foci, provided by one or more optic(s). Exemplary concentrators in accordance with the present invention preferably comprise a primary concentrating optic having one or more reflecting surfaces each having a respective line focus at an intermediate position between a top and bottom of a volume under concentrated illumination. Advantageously, positioning a line focus at such an intermediate position allows distribution of the heat load of the optical concentrator among more than one receiver locations when plural receivers are used. Optical concentrators in accordance with the present invention are preferably designed so the full entrance aperture is active. By active it is meant that, ignoring transmission and reflection losses inherent to suitable optical materials, any ray incident within the perimeter of the entrance aperture and substantially parallel to the plane formed by the optical axis and the concentration axis is collected by a receiver. Other advantages of optical concentrators in accordance with the present invention include a height to width ratio of individual concentrators favorable to dense packing of such concentrator in arrays of plural concentrators without sacrificing articulation range. Advantageously, some concentrators in accordance with the present invention only need a single axis of tracking. Such concentrators may be oriented so the concentration axis is substantially east to west so the optical axis tracks the seasonal changes in sun elevation while accepting the daily cosine law loss effects. Alternatively, such concentrators may be oriented so the concentration axis is substantially north-south so the optical axis tracks the daily changes in sun elevation while accepting seasonal cosine law loss effects.

Optical concentrating systems are provided in accordance with the present invention. Such optical concentrating system may be used as solar collectors, for example. Such systems concentrate light onto a device located near the focus of the optical system for the purpose of converting absorbed radiation into another useful form of energy such as electricity by a photovoltaic cell or heat by an energy absorber or other transducer. Optical concentrators and devices in accordance with the present invention relate to systems that concentrate light in a single dimension in at least one stage of concentration and may be generally referred to as linear or line concentrators. Additional optics may be used in parallel or series in accordance with the present invention.

High area efficient optical concentrators are also provided in accordance with the present invention. Such optical concentrators are preferably designed to minimize blocking of rays parallel to a plane formed by the optical axis and the concentration axis and incident on the aperture of the primary element thereby maximizing the area efficiency of the optical concentrator. Such optical concentrators provide high area efficiency by being designed to be compact and by preferably comprising aperture(s) that allow plural optical concentrators to be provided in an area with minimal spacing.

Systems comprising plural optical concentrators are also provided in accordance with the present invention. Preferably, plural optical concentrators are arranged in arrays, preferably parallel arrays wherein respective optical axes are preferably spaced apart by a distance that allows individual concentrators to articulate without colliding and/or interfering with adjacent concentrators. Individual optical concentrators can be articulated about a pivot axis parallel to the trough length, while not impinging on adjacent optical concentrators articulating in kind about their respective pivot axes. Optical concentrators in accordance with the present invention are preferably designed with a height/width ratio suitable for such dense arrangement thereby allowing a high area efficient system.

Devices that use self-refrigerating methods to dissipate excess thermal energy are provided in accordance with the present invention. Devices having high optical radiation concentration in compact packages, specifically those with photovoltaic elements, require dissipation of thermal energy resulting from inefficient conversion of radiation into electricity. Such thermal energy dissipation is achieved in accordance with the present invention, by passive self-refrigerating methods, such as natural convection, for example.

In a representative embodiment, first and second reflective surfaces are opposed so as to define a volume under optical concentration between such surfaces. In a preferred embodiment, the volume is at least partially defined by a trough, which trough is at least partially defined by the first and second reflective surfaces. A line focus of the first reflective surface is proximal to the second reflective surface. Similarly, a line focus of the second reflective surface is proximal to the first reflective surface. In accordance with the present invention, one or both focal lines are positioned intermediate between the top and bottom of the volume under optical concentration. A first exit aperture is associated with the second reflective surface in a manner effective to capture incident light focused onto the first exit aperture, and a second exit aperture is associated with the first reflective surface in a manner effective to capture incident light focused onto the second aperture. A first receiver element(s) is preferably positioned in optical communication with the first exit aperture and a second receiver element(s) is preferably positioned in optical communication with the second exit aperture. In preferred embodiments, a receiver is located outside the volume under optical concentration. In some embodiments, a receiver is positioned outside the trough. Optionally, one or more additional optical elements may be used to further concentrate light captured by the first exit aperture as such light travels from an exit aperture to the target element(s).

In another representative embodiment, an optical concentrator comprising a trough having first and second sides, a bottom, and a cover that defines an interior volume of the trough is provided. A reflective surface on the first side has a focus (line) generally proximal to the second side intermediate the bottom and cover. A secondary aperture positioned intermediate the cover and bottom is formed in the second side to capture concentrated light reflected from the first side. A receiver is in optical communication with the secondary aperture so that light captured by the secondary aperture travels along one or more pathways to the receiver. Optionally, one or more optical elements are in the pathway to further concentrate the light as it travels from the secondary aperture to the receiver.

In an aspect of the present invention, an optical concentrator is provided. The optical concentrator preferably comprises a body comprising a top and a bottom, an entrance aperture that allows radiation to be concentrated to enter an interior space of the body, an exit that allows concentrated radiation to leave the interior space of the body, a radiation receiver operatively positioned relative to and in optical communication with the exit, and a reflective surface positioned within the interior space the body comprising a line foci that provides a linear region of focused radiation to the exit. In accordance with the present invention, the exit is positioned at an intermediate position between the top and bottom of the body.

In another aspect of the present invention an optical concentrator is provided. The optical concentrator preferably comprises an optical axis, an axis of concentration, a body comprising a top and a bottom and comprising an entrance aperture that allows radiation to be concentrated to enter an interior space of the body, an exit that allows concentrated radiation to leave the interior space of the body, and a radiation receiver operatively positioned relative to and in optical communication with the exit, and a reflective surface positioned within the interior space the body, wherein the optical concentrator comprises a first field of view having a first angle and capable of collecting rays from a radiation source that are substantially parallel to a plane formed by the optical axis and axis of concentration, and a second field of view having a second angle substantially greater than the first angle and capable of collecting diffuse radiation, wherein rays of said diffuse radiation are from a direction different than substantially parallel to the radiation source.

In yet another aspect of the present invention, a method of concentrating radiation in a solar concentrator is provided. The method comprises the steps of causing solar radiation to impinge on one or more reflective surfaces of an optical concentrator, focusing the radiation to one or more linear focused region with the one or more reflective surfaces of the optical concentrator, and directing the one or more linear focused regions to one or more receivers positioned at an intermediate location between a top and bottom of the optical concentrator.

### BRIEF DESCRIPTION OF THE DRAWINGS

The accompanying drawings, which are incorporated in and constitute a part of this application, illustrate several aspects of the present invention and together with description of the embodiments serve to explain the principles of the invention. A brief description of the drawings is as follows:

FIG. 1 (Prior Art) is a cross-sectional view of a prior art optical concentrator having a two-sided receiver.

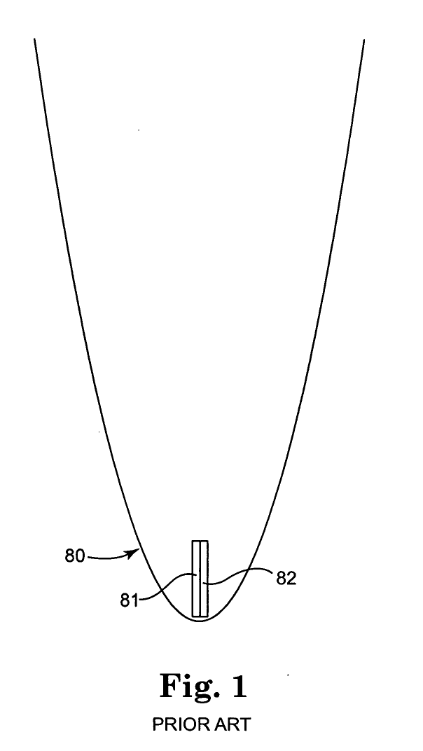

FIG. 2 (Prior Art) is a cross-sectional view of plural prior art optical concentrators showing in particular articulation restrictions in the form of a collision zone.

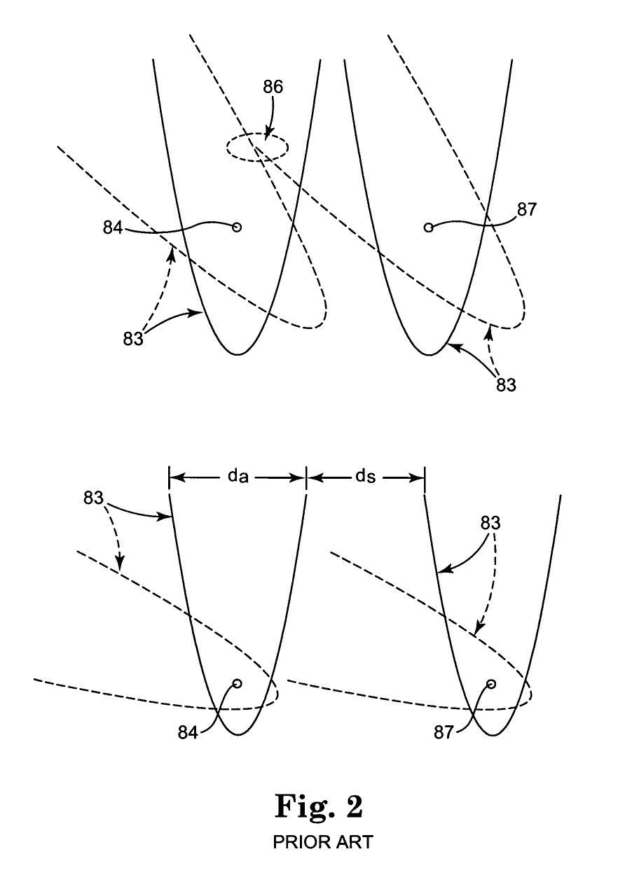

FIG. 3 (Prior Art) is a perspective view of a prior art optical concentrator showing in particular plural surfaces.

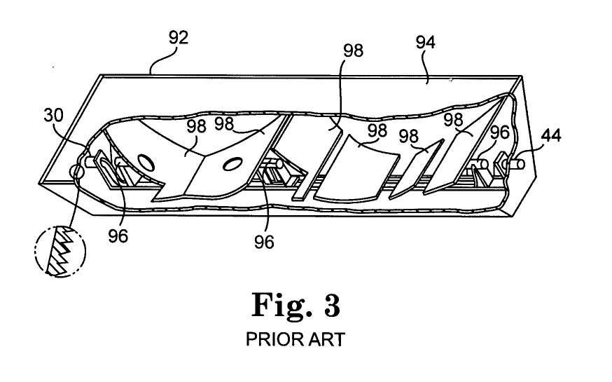

FIG. 4 is a perspective view of an exemplary optical concentrator in accordance with the present invention.

FIG. 5 is a cross-sectional view of the exemplary optical concentrator of FIG. 4 showing in particular a primary reflective optic and first and second optional secondary optics.

FIG. 6 is a schematic cross-sectional view of the primary optic for the optical concentrator of FIG. 5.

FIG. 7 is a schematic cross-sectional view of ray traces formed by the exemplary primary optic of the optical concentrator of FIG. 5.

FIG. 8 is a cross-sectional view of an alternative embodiment of an exemplary primary optic for an optical concentrator in accordance with the present invention.

FIG. 9 is a cross-sectional view of another exemplary optic for an optical concentrator in accordance with the present invention.

FIG. 10 is a cross-sectional view of yet another exemplary primary optic for an optical concentrator in accordance with the present invention.

FIG. 11 is a cross-sectional view of an exemplary secondary optic for an optical concentrator in accordance with the present invention.

FIG. 12 is a cross-sectional view showing the field of view of diffuse sky radiation for an exemplary optical concentrator in accordance with the present invention.

### DETAILED DESCRIPTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

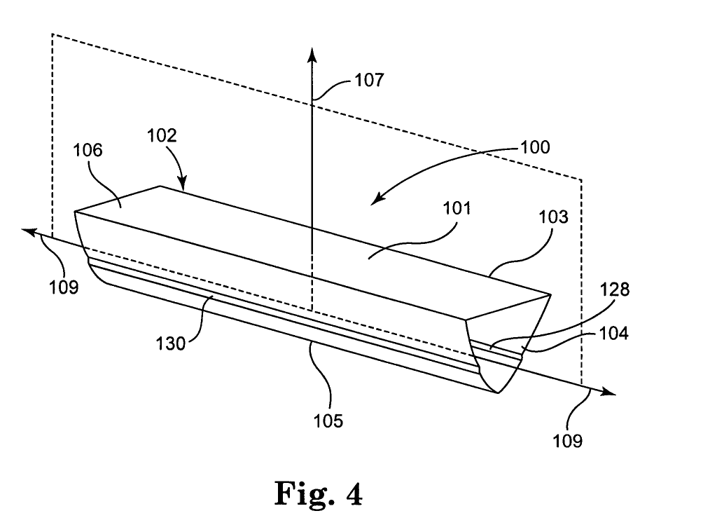

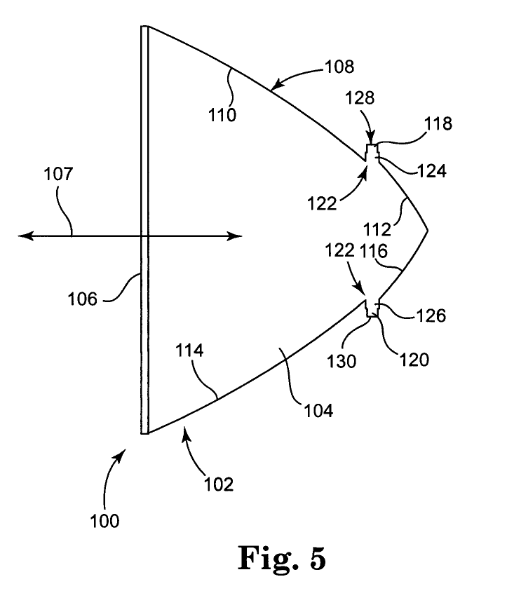

An exemplary optical concentrator 100 in accordance with the present invention is illustrated in FIGS. 4 and 5 and comprises optical axis 107 and concentrating axis 109. A perspective view of optical concentrator 100 is shown in FIG. 4, and a cross-sectional view is shown in FIG. 5. Optical concentrator 100 comprises body 102 having entrance aperture 101 to internal space 104 and optional cover 106. At least a portion of internal space 104 provides a volume under optical concentration. Body 102 is often referred to as a trough or enclosure and comprises top 103 and bottom 105. Cover 106 functions to allow radiation to enter internal space 104 of body 102 where the light is concentrated and also functions to seal and protect body 102 from the surrounding environment. Cover 106 is preferably substantially transparent to the particular radiation desired to be concentrated and may comprise materials such as acrylic or glass, for example. Cover 106 may also include any desired lenses, optics, coatings, or the like but desirably does not serve as an optical concentrating element of concentrator 100 when the capturing of diffuse radiation for self-power is desired.

As illustrated, optical concentrator 100 comprises primary optic system 108 having reflective surfaces 110, 112, 114, and 116. Optical concentrator 100 also includes first and second receivers, 118 and 120, respectively, that function to collect radiation, such as photovoltaic cells or the like. Optical concentrator 100 also preferably comprises one or more secondary optics such as optional secondary optic system 122 having first optic 124 operatively positioned relative to first receiver 118 and second optic 126 operatively positioned relative to second receiver 120. Preferably, receiver 118 and first optic 124 of the secondary optic system 122 (if used) are positioned at a first discontinuity (or gap) 128 between reflective surface 110 and reflective surface 112. First discontinuity 128 functions as an exit aperture for concentrated radiation to leave internal space 104 (the volume under optical concentration). Also, receiver 120 and second optic 126 of the secondary optic system 122 (if used) are positioned at a second discontinuity 130 between reflective surface 114 and reflective surface 116.

Surfaces 110, 112, 114, and 116 preferably comprise parabolic or parabolic-like surfaces. Preferably, the top surfaces 110 and 114 share a common foci with the bottom surfaces 112 and 116, respectively. Preferably, such foci are coincident or near coincident with the opposing side of the primary optic. Contemplated parabolic surfaces may either be formed as a single element or may be formed as separate sub-elements. Contemplated primary and secondary optic systems may be constructed of high-reflectivity, aluminum sheet metal manufactured by Alanod under the trade name MIRO™ (distributed by Andrew Sabel, Inc., Ketchum, Id.).

As mentioned, in some embodiments, primary optic system comprises plural reflective surfaces, where such surfaces are preferably formed from one or more sub-elements, and may have parabolic profiles. In other embodiments, primary optic system preferably comprises at least four parabolic surfaces including two on each side of the optical axis of the primary optic system where such two surfaces are separated by a discontinuity or gap. In some embodiments, optical concentrators comprise a ratio between the input aperture and the receiver area greater than ten, preferably between 12 and 20 depending on the desired concentration.

Devices, methods, and apparatus utilized for self-refrigeration may include: plural heat spreader elements in thermal contact with receiver elements, plural convective fins arranged around the heat spreader elements, and the like. Contemplated heat spreader elements are designed to interconnect at least one of the primary optic(s), at least one of the secondary optic(s) (if used), or a combination thereof. Contemplated convective fins may comprise independently at least one primary optic, at least one secondary optic (if used), at least one additional fin not part of the primary and second optic or a combination thereof. In some embodiments, a receiver or self-refrigerators are preferably arranged outside the primary optic. The receiver(s) may be in contact directly or indirectly with one or more of a primary or optional secondary concentrator optic allowing them to serve as self-refrigerating mechanisms for the receiver(s). Contemplated receivers can be arranged such that the field of view of the sky of the receiver encompasses a significant portion of the entrance aperture of the primary optic.

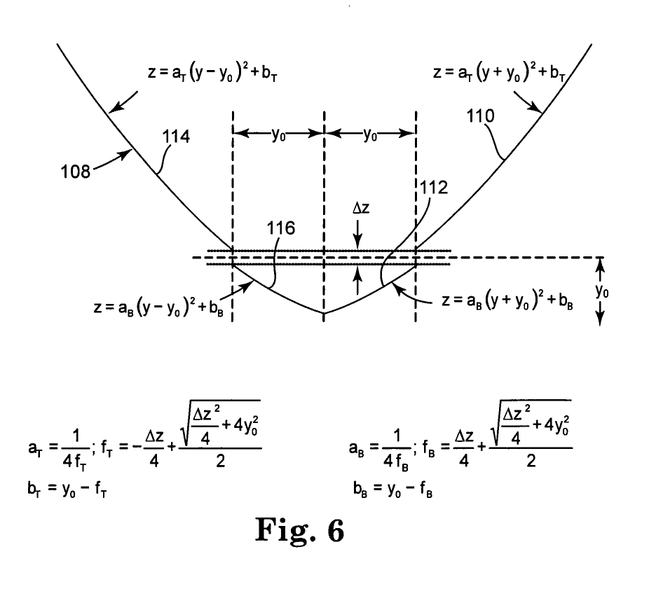

The primary optic 108 of optical concentrator 100 is schematically shown in FIG. 6, and includes for purposes of illustration with respect to this embodiment parabolic surfaces 110, 112, 114, and 116 having general form:

z=a(y±y₀)²+t

### Where y₀ specifies the location of the respective foci (y₀,y₀) and (−y₀,y₀). Coefficients a and b of the above equation are a function of y₀ and the separation Δz 20 between the upper (110 and 114) and lower (112 and 116) surfaces.

$${a}_{T} = \frac{1}{4 {f}_{T}} ; {f}_{T} = - \frac{Δ z}{4} + \frac{\sqrt{\frac{Δ {z}^{2}}{4} + 4 {y}_{0}^{2}}}{2} {b}_{T} = {y}_{0} - {f}_{T}$$

$${a}_{B} = \frac{1}{4 {f}_{B}} ; {f}_{B} = \frac{Δ z}{4} + \frac{\sqrt{\frac{Δ {z}^{2}}{4} + 4 {y}_{0}^{2}}}{2} {b}_{B} = {y}_{0} - {f}_{B}$$

In these forms, parabolic surfaces 114 and 116 focus rays parallel to the optical axis toward the focus located on the opposing side at (y₀,y₀), whereas the parabolic surfaces 110 and 112 focus parallel to the optical axis toward the focus located on the opposing side at (−y₀,y₀). It should be noted that the above equations illustrate one exemplary embodiment and that alternate embodiments result from perturbations to these general formulae.

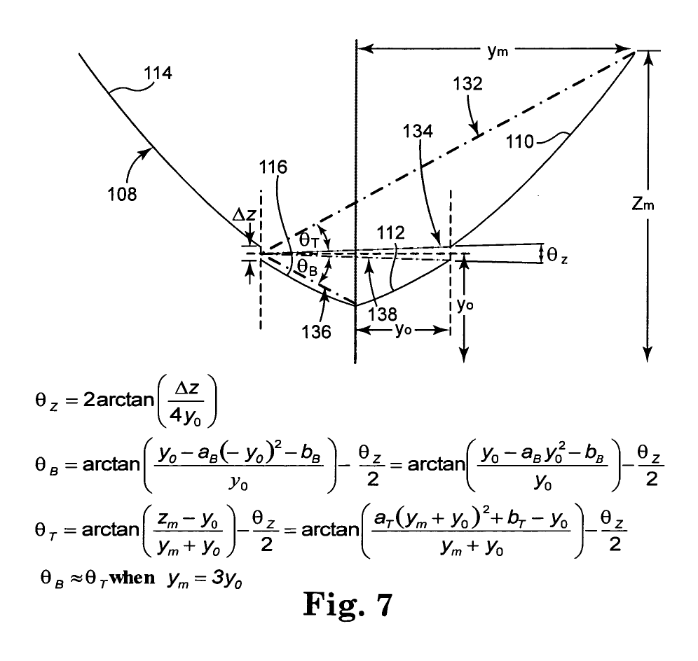

In FIG. 7, rays parallel to the optical axis incident on parabolic surface 110 form a ray bundle that has an angular spread θ_{T} defined by rays 132 and 134 reflected off the top and bottom extremity of the surface respectively. Similar rays incident on parabolic surface 112 form a ray bundle that has angular spread θ_{B} defined by rays 136 and 138 reflected off the top and bottom extremity of the surface respectively. The angle θ_{Z} represents an angular gap in the total ray bundle incident on the foci of the parabolic surfaces. In contemplated embodiments, these angles are specified by the following equations:

$${θ}_{Z} = 2 arc tan ( \frac{Δ z}{4 {y}_{0}} )$$

$${θ}_{B} = arc tan ( \frac{{y}_{0} - {{a}_{B} ( - {y}_{0} )}^{2} - {b}_{B}}{{y}_{0}} ) - \frac{{θ}_{Z}}{2} = arc tan ( \frac{{y}_{0} - {a}_{B} {y}_{0}^{2} - {b}_{B}}{{y}_{0}} ) - \frac{{θ}_{Z}}{2}$$

$${θ}_{T} = arc tan ( \frac{{z}_{m} - {y}_{0}}{{y}_{m} + {y}_{0}} ) - \frac{{θ}_{Z}}{2} = arc tan ( \frac{{{a}_{T} ( {y}_{m} + {y}_{0} )}^{2} + {b}_{T} - {y}_{0}}{{y}_{m} + {y}_{0}} ) - \frac{{θ}_{Z}}{2}$$

$${θ}_{B} \approx {θ}_{T} when {y}_{m} = 3 {y}_{0}$$

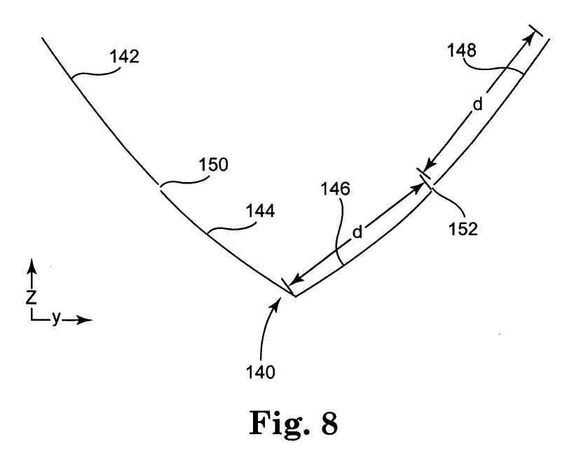

In FIG. 8, an exemplary primary optic 140 for an optical concentrator in accordance with the present invention is schematically shown. Primary optic 140 includes reflective surfaces 142, 144, 146, and 148 as well as apertures 150 and 152. As illustrated, the location of each foci corresponds with apertures 150 and 152, respectively, and is centered along the respective trough wall so that the length of surface 142 is equal or near equal to the length of surface 144 and the length of surface 148 is equal or near equal to the length of surface 146. This arrangement has the advantage that it centers the thermal load along the trough wall. Reflective or refractive secondary optics can be used if desired.

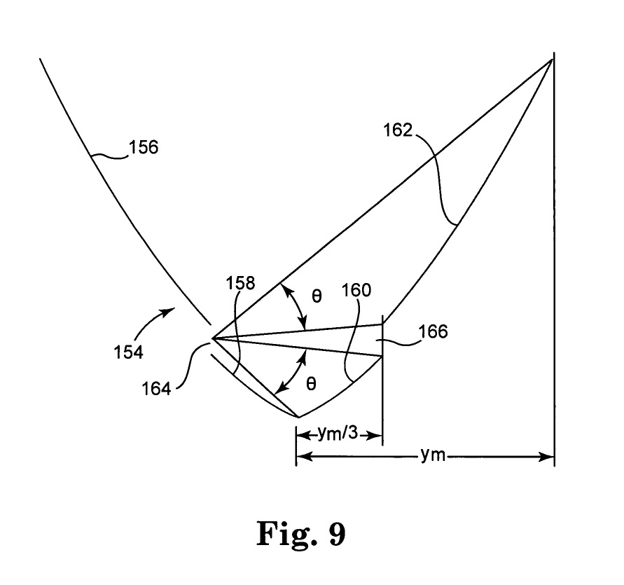

As an example, another exemplary primary optic 154 for an optical concentrator in accordance with the present invention is schematically shown in FIG. 9. Primary optic 154 includes reflective surfaces 156, 158, 160, and 162 as well as apertures 164 and 166. As shown, the location of the foci is ⅓ of the trough width (y₀=yₘ/3). This arrangement has the advantage that the angular spread of incident rays from surface 156 or surface 162 is equal to the angular spread of incident rays from surface 158 or surface 160, respectively. Reflective or refractive secondary optics can be used if desired.

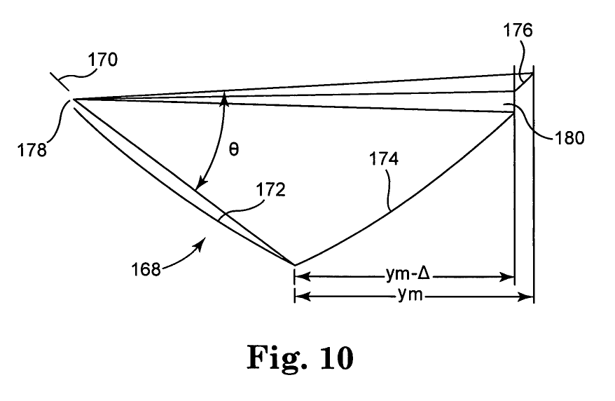

In FIG. 10, another exemplary primary optic 168 for an optical concentrator in accordance with the present invention is schematically shown. Primary optic 168 includes reflective surfaces 170, 172, 174, and 176 as well as apertures 178 and 180. As shown, the location of the foci is near the top of the trough (y₀˜yₘ) and may be at the top of the trough. This arrangement has the advantage that it minimizes the total angular spread of incident rays and has a minimized height/width ratio. Reflective or refractive secondary optics can be used if desired.

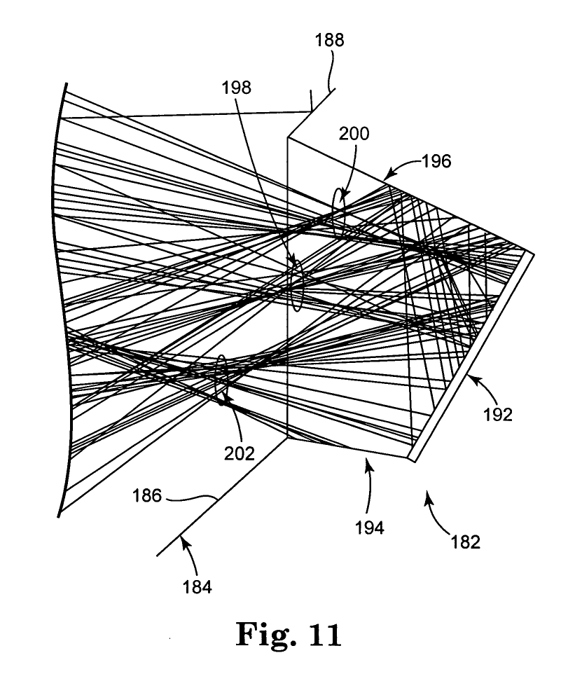

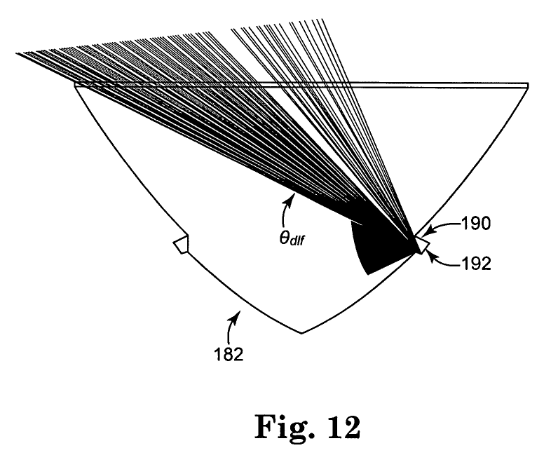

In FIGS. 11 and 12, another exemplary optical concentrator 182 in accordance with the invention is schematically shown. Optical concentrator 182 includes primary optic 184 having reflective surfaces 186 and 188, secondary optic 190, and receiver 192. As illustrated, optional secondary optic 190 comprises reflective surfaces 194 and 196 which function to direct rays focused by primary optic 184 onto receiver 192. Ray group 198 represents on axis rays whereas ray groups 200 and 202 represent slightly off axis rays in each direction, respectively. This arrangement increases the direct field of view thereby decreasing the pointing sensitivity of the optical concentrator. Secondary concentrating elements increase the concentration ratio and allow for smaller receiver elements to be utilized. Refractive secondary optics can be used if desired.

FIG. 12 illustrates how the secondary optic 190 advantageously allows the receiver 192 to be oriented at an angle suitable for receiving diffuse sky radiation characterized by the field of view angle θ_{diff}. Note also that for simplicity only one side of the diffuse radiation is illustrated. As such, receiver 192 is able to generate power even when the optical axis of the component is not aligned to the primary radiation source, such as the sun. This power may advantageously be used in conjunction with like power from a set of like components to articulate these components. This arrangement provides a mechanism by which self-powering of an articulated set of these optics may be realized using background radiation, such as diffuse sky radiation.

In accordance with the present invention, an optional secondary optic(s) may be formed as part of a primary optic(s) or formed as a separate entity from a primary optic(s). That is, a single reflective surface may be used to provide all or a portion of both the primary and secondary optic. In an alternative embodiment, a secondary optic(s) may be formed from a solid refractive material such that the surface at the entrance aperture refracts rays towards a receiver, and the walls of the secondary optic(s) are such that incident rays may totally internally reflect onto the receiver. Optional secondary optics may comprise plural reflective surfaces or may comprise at least one transparent refractive material.

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

What is claimed is:

1. An optical concentrator, the optical concentrator comprising:
a body comprising a top and a bottom and comprising an entrance aperture that allows radiation to be concentrated to enter an interior space of the body, an exit that allows concentrated radiation to leave the interior space of the body, the exit positioned at an intermediate position between the top and bottom of the body, and a radiation receiver operatively positioned relative to and in optical communication with the exit; and
a reflective surface positioned within the interior space the body comprising a line focus that provides a linear region of focused radiation to the exit.

2. The optical concentrator of claim 1, wherein the body comprises a trough.

3. The optical concentrator of claim 1, wherein the radiation receiver comprises a photovoltaic cell.

4. The optical concentrator of claim 1, wherein the reflective surface comprises a parabolic surface.

5. The optical concentrator of claim 1, further comprising a cover that at least partially enclosed the interior space of the body and that allows radiation to be concentrated to enter the interior space of the body.

6. The optical concentrator of claim 1, further comprising plural reflective surfaces.

7. The optical concentrator of claim 6, further comprising plural exits.

8. The optical concentrator of claim 1, further comprising an additional optic operatively positioned at the exit and distinct from the reflective surface.

9. The optical concentrator of claim 8, wherein the additional optic comprises a reflective optic.

10. The optical concentrator of claim 8, wherein the additional optic comprises a refractive optic.

11. The optical concentrator of claim 1, further comprising one or more self-refrigeration device.

12. The optical concentrator of claim 11, wherein the one or more self-refrigeration device comprises one or more of a heat spreader and a cooling fin.

13. The optical concentrator of claim 1, comprising an unobstructed light path between the entrance aperture and the radiation receiver.

14. An optical concentrator, the optical concentrator comprising:
an optical axis;
an axis of concentration;
a body comprising a top and a bottom and comprising an entrance aperture that allows radiation to be concentrated to enter an interior space of the body, an exit that allows concentrated radiation to leave the interior space of the body, and a radiation receiver operatively positioned relative to and in optical communication with the exit; and
a reflective surface positioned within the interior space the body;
wherein the optical concentrator comprises a first field of view having a first angle and capable of collecting rays from a radiation source that are substantially parallel to a plane formed by the optical axis and the axis of concentration, and a second field of view having a second angle substantially greater than the first angle and capable of collecting diffuse radiation, wherein rays of said diffuse radiation are from a direction different than substantially parallel to the radiation source.

15. The optical concentrator of claim 14, wherein the exit is positioned at an intermediate position between the top and bottom of the body.

16. The optical concentrator of claim 14, wherein the reflective surface comprises a parabolic surface.

17. The optical concentrator of claim 14, further comprising plural reflective surfaces.

18. The optical concentrator of claim 17, further comprising plural exits.

19. A method of concentrating radiation in a solar concentrator, the method comprising the steps of:
causing solar radiation to impinge on one or more reflective surfaces of an optical concentrator;
focusing the radiation to one or more linear focused region with the one or more reflective surfaces of the optical concentrator; and
directing the one or more linear focused regions to one or more receivers positioned at an intermediate location between a top and bottom of the optical concentrator.

20. The method of claim 19, wherein the optical concentrator comprises any of the optical concentrators recited in claims 1-18.
